(19) United States
(12) Patent Application Publication
(10) Pub. No.: US 2025/0306130 A1
(43) Pub. Date: Oct. 2, 2025

(54) METHOD FOR TESTING A WIRING OF AN ELECTRICAL INSTALLATION

(71) Applicant: OMICRON electronics GmbH, Klaus (AT)

(72) Inventor: Josef Schmidbauer, Salzburg (AT)

(21) Appl. No.: 18/864,512

(22) PCT Filed: May 15, 2023
(86) PCT No.: PCT/EP2023/062961

§ 371 Date: Nov. 8, 2024

(30) Foreign Application Priority Data
May 17, 2022 (AT) A50348/2022

(51) Int. Cl. G01R 31/55; G01R 31/58; G01R 31/67

(52) U.S. Cl. CPC G01R 31/55; G01R 31/58; G01R 31/67

(57) ABSTRACT

The present invention relates to a method (200) for testing a wiring of an electrical installation (100) comprising multiple circuits. In the method (100), multiple test signals (160-162) are generated. Each of the multiple test signals (160-162) has an asymmetrical signal shape in the time domain and also a combination of harmonics from a predefined group of higher harmonics. The combinations of harmonics of the multiple test signals (160-162) are different. The multiple test signals (160-162) are fed at a first point (141) of the electrical installation (100) into multiple first connections (142-144), which are assigned to the multiple circuits. Multiple measurement signals are detected at multiple second connections (146-148), which are assigned to the multiple circuits, at a second point (145) of the electrical installation (100). On the basis of the fed test signals (160-162) and the detected measurement signal, assignments between a first connection of the multiple first connections (142-144) and a second connection of the multiple second connections (146-148) are determined.

### FIELD OF THE INVENTION

The present invention relates to a method for testing wiring of an electrical installation, in particular for testing wiring of an electrical installation having multiple circuits, for example a power engineering electrical installation in for example a substation or a power plant.

### BACKGROUND

Wiring errors may occur when installing, repairing or extending an electrical installation, for example in a substation or a power plant. Particularly in installations having multiple circuits and/or multiple phases, for example installations for three-phase AC current, conductors may be mixed up; for example two outer conductors may be mixed up, or an outer conductor may be mixed up with the neutral conductor. Furthermore, a polarity may for example be reversed when connecting a transformer. Therefore, before an electrical installation is commissioned or recommissioned, the wiring is usually tested in order to establish incorrectly connected conductors and reversed polarities.

By way of example, test signals may be injected successively into the individual phases at an injection point and a measurement signal may be acquired at a measuring point remote from said injection point and at which an effect of the test signal should occur if the wiring is correct. If the expected effect of the test signal is not detected at the measuring point, a wiring error could be present. This procedure is comparatively time-consuming since numerous measurements have to be performed in order to check multiple circuits and phases, and the measuring device has to be connected accordingly to the injection point and the measuring point for each measurement. Furthermore, although such a measurement may be used to establish that a wiring error is present, it is not possible to directly establish the type of the wiring error, for example, whether conductors have been mixed up or not connected.

Many power engineering systems use a three-phase current system. Likewise, many test devices have at least three current or voltage outputs. These test devices may therefore be used to inject test signals in parallel and to test the wiring of all phases in one operation. By way of example, a test signal having different amplitudes for the different phases may be used for this purpose. It is possible here in particular to use amplitudes for currents and voltages the combination and/or subtraction of which give rise to new amplitudes that otherwise do not occur.

### EXAMPLE

| | | | |
|---|---|---|---|
| L1 = 3 | L1 + L2 = 8 | L1 − L2 = −2 | L1 + L2 + L3 = 17 |
| L2 = 5 | L1 + L3 = 12 | L1 − L3 = −6 | L1 + L2 − L3 = −1 |
| L3 = 9 | L2 + L3 = 14 | L2 − L3 = −4 | L1 − L2 + L3 = 7 |
| | | | −L1 + L2 + L3 = 11 |

This makes it possible to detect wiring errors based on the measured amplitude, for example if the return conductor of one phase is connected incorrectly.

However, the current or voltage amplitudes have to differ to a relatively great extent in order to be able to perform an unambiguous assignment. It is therefore not always possible to work with amplitudes close to the nominal range of the equipment (for example 1 A, 5 A or 100 V). It is also often the case in practice that there are multiple parallel connections or ground connections. In these cases, a current division or voltage division is implemented depending on the respective resistances.

Unambiguous phase detection is then no longer possible.

### SUMMARY OF THE INVENTION

There is a need for improved options for testing wiring of an electrical installation having multiple circuits, these options being able to be performed quickly and reliably using simple means.

According to the present invention, provision is made for a method for testing wiring of an electrical installation having multiple circuits and a test device for testing wiring of an electrical installation having multiple circuits, as defined in the independent claims. The dependent claims define embodiments of the invention.

A method according to the invention for testing wiring of an electrical installation having multiple circuits comprises generating multiple test signals. Each of the multiple test signals has a waveform that is asymmetric in the time domain and a combination of harmonics from a predefined group of higher harmonics. The waveform that is asymmetric in the time domain may be the same for all of the multiple test signals.

The following designations are used for this description. A fundamental of the frequency f is referred to as first harmonic. A double-frequency oscillation (2f) is referred to as second harmonic. Generally speaking, the oscillation with the n-times frequency nf is the nth harmonic. Higher harmonics is the name given to all harmonics other than the first harmonic. The nth harmonic is referred to here as the (n-1)th higher harmonic.

The waveform that is asymmetric in the time domain comprises a first harmonic (fundamental). The waveform is periodic with the frequency of this fundamental. Asymmetric in the time domain means that the waveform, which is plotted as a signal level over time, cannot be mapped to itself by mirroring on an axis perpendicular to the time axis. One example of such a waveform that is asymmetric in the time domain is the tilting oscillation or sawtooth oscillation with for example a rising edge having a small slope and a falling edge having a large (but negative) slope in terms of magnitude.

The combinations of harmonics of the multiple test signals are different, that is to say each test signal has its own unique combination of harmonics.

By way of example, each of the multiple test signals may have a waveform that is asymmetric in the time domain and that is formed by way of a superimposition of a first harmonic, a second harmonic and a third harmonic each having corresponding amplitude factors. In this case, the waveform that is asymmetric in the time domain comprises, for example, in addition to a fundamental, at least a second and third harmonic. In another example, the waveform that is asymmetric in the time domain may comprise, in addition to the fundamental, only either the second or third harmonic. The waveform that is asymmetric in the time domain that is thus formed may additionally have a combination of further higher harmonics having corresponding amplitude factors superimposed on it, for example a combination of fourth harmonic and fifth harmonic. In other words, in this case, the predefined group of higher harmonics comprises the fourth and fifth harmonics. A first combination, which is assigned for example to a first test signal of the multiple test signals, may have a fourth harmonic and no fifth harmonic. The first test signal thus comprises the first, second, third and fourth harmonics. A second combination, which is assigned for example to a second test signal of the multiple test signals, may comprise a fifth harmonic, but not the fourth harmonic. The second test signal thus comprises the first, second, third and fifth harmonics. A third combination, which is assigned for example to a third test signal of the multiple test signals, may have neither the fourth nor the fifth harmonic. The third test signal thus comprises only the first, second and third harmonics.

Overall, for example, the combination of the harmonics of the multiple test signals is designed such that any linear combinations of the multiple test signals essentially also have the same asymmetric properties in the time domain as the individual test signals. This may be achieved for example in that the test signals differ from one another only in terms of the higher harmonics (for example the fourth and fifth harmonics) and are phase-synchronous with regard to the fundamental. If the higher harmonics (for example the fourth and fifth harmonics) are coded accordingly, it is also possible to detect which individual signals occur in a sum signal, that is to say the linear combination. The individual signals are thus able to be detected, but it is also easy, for the sum signal, to establish the partial signals of which it consists.

The multiple test signals thus generated are injected into multiple first connections, which are assigned to the multiple circuits of the electrical installation, at a first point of the electrical installation. The multiple circuits may for example comprise multiple phases of the electrical installation. A different test signal of the multiple test signals is injected into each first connection of the multiple first connections. In other words, a different test signal is injected into each circuit of the electrical installation at the first point. At a second point of the electrical installation, multiple measurement signals are acquired at multiple second connections, which are assigned to the multiple circuits.

By way of example, in the case of a substation, the first point may be at an input of the substation and the second point may be at one of the outputs of the substation. In another example, the first point may be on a first side of a transformer and the second point may be on a second side of the transformer. The injected test signals and the acquired measurement signals are taken as a basis for determining an assignment between in each case a first connection of the multiple first connections and a second connection of the multiple second connections in order for example to test the wiring of the electrical installation on the basis of the assignments. Since the injected test signals are different, it is possible to establish unambiguously which test signal at which of the second connections has led to a corresponding measurement signal, such that it is possible to determine an unambiguous assignment between the first connections and the second connections. By way of example, it is possible to easily establish mix-ups, but also interruptions, based on the test signals.

By way of example, in the case of a wiring error, it is possible to ascertain an assignment that does not correspond to a desired or predefined assignment, or no assignment, or no complete assignment, is possible, for example due to interruptions or couplings with completely incorrect circuits. In the error-free case, on the other hand, it is possible to ascertain an assignment that corresponds to a predefined “target assignment”.

The presence or absence of a certain harmonic, for example the fourth or fifth harmonic, thus results in a kind of digital coding of the test signals. Adding the sixth harmonic makes it possible to increase the number of different combinations and thus the number of different test signals, in order for example to enable test signals for testing wiring of an electrical installation having more than three phases or circuits, for example for testing two three-phase installation parts, that is to say a total of six phases, or installation parts having multiple circuits, for example having six or more circuits.

The multiple test signals may be injected simultaneously into the multiple first connections. The multiple measurement signals may likewise be acquired simultaneously. Due to the coding of the test signals based on the different combinations of harmonics that they contain, the multiple measurement signals that are acquired at the second point of the electrical installation are able to be assigned unambiguously to the corresponding test signals, even if the test signals are carried simultaneously by the electrical installation. Appropriate measurement wiring for injecting the test signals and for capturing the measurement signals may therefore be implemented at a point in time, and the wiring may be checked without changing the measurement wiring. The wiring is thereby able to be tested quickly. Wiring errors are able to be avoided because the measurement wiring does not have to be changed in order to check the wiring of all circuits and/or phases.

According to one embodiment, the first harmonic, that is to say the fundamental, of the waveform that is asymmetric in the time domain has a frequency that is not equal to a mains frequency or nominal frequency of the electrical installation. The first harmonic of the waveform that is asymmetric in the time domain may for example have a frequency in the range of 50 to 60 Hz, in particular a frequency in the range of 51 to 55 Hz, for example a frequency of 52.63 Hz. Since the first harmonic of the test signals is not equal to the mains frequency of the electrical installation, it is possible to avoid interference from other installation parts that are in operation. Installation parts that are in operation usually generate interference signals at mains frequency, that is to say for example at 50 Hz or 60 Hz, as well as interference signals having higher harmonics thereof. If the fundamental and the higher harmonics of the test signals deviate from this mains frequency and the corresponding higher harmonics, the interference signals from other installation parts that are in operation are easily able to be detected in the measurement signals and filtered out. Since the fundamental of the waveform that is asymmetric in the time domain has a frequency that does not deviate to a great extent from the nominal frequency of the electrical installation, the test signals are suitable for transmission via the electrical installation, for example via current or voltage converters having transformers and/or capacitances.

In one embodiment, an amplitude of an nth harmonic of the group of higher harmonics has an amplitude factor of 1/n² relative to an amplitude of a fundamental of the waveform that is asymmetric in the time domain. The second and third harmonics described above may also have a corresponding amplitude factor. Such amplitude factors make it possible to achieve the waveform that is asymmetric in the time domain. Waveforms that comprise the first to third harmonics and a combination of further higher harmonics, for example fourth and/or fifth and/or sixth harmonics, have for example a sawtooth-like waveform having a steep rising edge and a shallow falling edge, such that the waveform is asymmetric in the time domain. Furthermore, the test signals generated in this way have substantially no DC component on average, such that it is possible to avoid saturation of current or voltage converters in the electrical installation.

According to one embodiment, the assignments are determined by filtering the measurement signals using bandpass filters the center frequencies of which correspond to the frequencies of the harmonics from the predefined group of higher harmonics. The filtered measurement signals are compared with a threshold value. The threshold value may be set depending on an amplitude of a fundamental of the waveform that is asymmetric in the time domain. Since the harmonics of the test signal do not normally occur in the electrical installation, the threshold value is able to be set to be comparatively low, for example to one percent of the fundamental, such that even weak signals are also able to be assigned unambiguously. The above-described coding of the test signals makes it possible to perform an assignment between measurement signals and test signals, that is to say between first connections and second connections, with comparative ease by checking for the presence of a signal level at outputs of the bandpass filters.

In a further embodiment, the assignments are determined by determining, in the measurement signals, amplitudes of the frequencies corresponding to the frequencies of the harmonics from the predefined group of higher harmonics. These amplitudes may be determined for example by way of a discrete Fourier transform. The amplitudes determined in this way are each compared with a threshold value. As described in the previous embodiment, the threshold value may be set to be comparatively low, for example to one percent of the fundamental, such that even small amplitudes are able to be detected unambiguously. The above-described coding of the test signals makes it possible to perform an assignment between measurement signals and test signals, that is to say between first connections and second connections, with comparative ease by checking for the presence of a signal level at frequencies of the corresponding harmonics.

The coding of test signals by adding a combination of higher harmonics to the waveform that is asymmetric in the time domain will be described in detail below in the form of three embodiments.

In one embodiment, the predefined group of higher harmonics comprises a fourth harmonic and a fifth harmonic. The combinations for the various test signals are selected as follows, as already described above: a first combination comprises the fourth harmonic, but not the fifth harmonic. A corresponding digital representation of this combination may be denoted by 10, wherein the first digit represents the presence (1) or the absence (0) of the fourth harmonic and the second digit represents the presence (1) or the absence (0) of the fifth harmonic. A second combination comprises the fifth harmonic, but not the fourth harmonic. The corresponding digital representation of this combination is 01. A third combination comprises neither the fourth nor the fifth harmonic, and the corresponding digital representation of this combination is 00. With a combination of only two harmonics, it is therefore possible to provide a sufficient number of test signals for testing an electrical installation having three phases.

In a further embodiment, the predefined group of higher harmonics comprises, in addition to the fourth and fifth harmonics, also a sixth harmonic. Combinations for the various test signals may be selected as follows, with only the corresponding digital representation of these combinations being listed for simplification. In this digital representation, the first digit denotes the presence (1) or the absence (0) of the fourth harmonic, the second digit denotes the presence (1) or the absence (0) of the fifth harmonic, and the third digit denotes the presence (1) or the absence (0) of the sixth harmonic. A first combination is for example 100, a second combination is for example 010, and a third combination is for example 001. With these combinations, it is possible to provide a sufficient number of test signals for testing an electrical installation having three phases, with the Hamming distance between the three combinations being two, such that it is possible to reliably detect the combinations even in the case of noisy signals or signals subject to interference.

In yet another embodiment, the predefined group of higher harmonics comprises the fourth, fifth and sixth harmonics. Combinations for the various test signals may be selected as follows, with again only the corresponding digital representation of these combinations being listed for simplification. A first combination is for example 001, a second combination is for example 010, a third combination is for example 011, a fourth combination is for example 100, a fifth combination is for example 101, and a sixth combination is for example 110. With these combinations, it is possible to provide a sufficient number of test signals for testing an electrical installation having two times three phases or up to eight circuits.

In a further embodiment, the predefined group of higher harmonics additionally comprises amplitude factors that are able to be assigned to the higher harmonics. An unambiguous combination of harmonics assigned to the respective test signal may additionally comprise one or more amplitude factors from the predefined group. By way of example, a first combination may have a certain higher harmonic, for example the fourth harmonic, having a first amplitude factor, for example having the amplitude factor 1/16. A second combination of the different combinations may have the same higher harmonic, that is to say the fourth harmonic, having a second amplitude factor, for example the amplitude factor 1/24. A third combination of the different combinations may have the same higher harmonic, that is to say the fourth harmonic, having a third amplitude factor, for example the amplitude factor 1/48. It should be noted that the amplitude factors, that is to say the first, second and third amplitude factors in the example, are different. Further combinations may be based for example on another higher harmonic, for example the fifth harmonic. With appropriate coding, it is possible to distinguish between phases of multiple multi-phase systems, for example multiple three-phase systems, or multiple circuits, and their wiring is thus able to be tested simultaneously.

According to a further embodiment, the method furthermore comprises determining polarities of the acquired measurement signals in order to test the wiring of the electrical installation depending on the determined polarities. In particular, the asymmetric waveform of the test signals in the time domain may enable simple and reliable determination of the polarity. If for example the wiring of a transformer is incorrect, for example if connections on one side of the transformer have been mixed up, the measurement signal may have a polarity opposite that of the corresponding test signals. In the case of a waveform that is asymmetric in the time domain, the opposite polarity is able to be detected easily. If for example the test signal has a steep rising edge and a shallow falling edge, a measurement signal having opposite polarity has a shallow rising edge and a steep falling edge. A corresponding error in the wiring is thus able to be established.

To determine polarities of the acquired measurement signals, it is possible, for example, for a respective measurement signal of the acquired measurement signals, to determine a derivative of the measurement signal and to generate a comparison signal by comparing the derivative with a threshold value. By way of example, the comparison signal may have a positive value for ranges of the derivative having a positive slope above the threshold value and negative value, of equal absolute value, for ranges of the derivative having a negative slope above the threshold value. If the average of the comparison signal is then determined, for example as a sliding average or over a period of the fundamental of the test signal, the polarity of the measurement signal is able to be determined on the basis of the average of the comparison signal.

As an alternative or in addition, determining polarities of the acquired measurement signals for a respective measurement signal may comprise determining a correlation coefficient, in particular a correlation factor, on the basis of the respective measurement signal and the waveform that is asymmetric in the time domain. The polarity of the respective measurement signal may be determined on the basis of the correlation factor. In the case of identical polarity, the correlation factor is positive and has for example a value close to 1. In the case of opposite polarity, the correlation factor is negative and has for example a value close to −1.

A test device according to the invention for testing wiring of an electrical installation having multiple circuits comprises a test signal generation device, an injection device, an acquisition device and a processing device. The test signal generation device is configured to generate multiple test signals. Each of the multiple test signals has a waveform that is asymmetric in the time domain and a combination of harmonics from a predefined group of higher harmonics. The combinations of harmonics of the multiple test signals are different. The injection device is configured to inject the multiple test signals into multiple first connections at a first point of the electrical installation. The multiple first connections are assigned to the multiple circuits of the electrical installation. A different test signal of the multiple test signals is injected into each first connection of the multiple first connections. Since the test signals are based on different combinations of harmonics, the test signals injected into the multiple first connections at the first point are different. The acquisition device is configured to acquire multiple measurement signals at multiple second connections, which are assigned to the multiple circuits, at a second point of the electrical installation. The first point and the second point are different points of the electrical installation. The multiple circuits may for example comprise multiple phases of the electrical installation. By way of example, the first point may be on one side of a transformer of the electrical installation and the second point may be on the other side of the transformer. The acquisition device is configured to determine assignments between in each case a first connection of the multiple first connections and a second connection of the multiple second connections on the basis of the injected test signals and the acquired measurement signals.

The test signal generation device may comprise multiple single-phase devices that each generate only one test signal. The multiple single-phase devices may be configured such that they each generate one of the multiple test signals based on different combinations of harmonics. As an alternative or in addition, the test signal generation device may comprise multiple multi-phase devices, for example two three-phase devices, in order to generate six test signals using which six circuits or phases are able to be tested simultaneously. The devices may in this case be connected in order to achieve the same phase position, which simplifies the detection of superimposed signals. However, the detection of the individual phases also works when the devices are not coupled.

The test device may be designed in particular to perform the method described above or one of its embodiments and therefore also comprises the advantages described above in connection with the method.

### BRIEF DESCRIPTION OF THE FIGURES

The invention is explained in more detail below on the basis of the drawings with reference to embodiments. In the drawings, identical reference signs refer to identical elements.

FIG. 1 schematically shows a test device for testing wiring of an electrical installation having multiple phases according to one embodiment.

FIG. 2 shows a method for testing wiring of an electrical installation having multiple phases according to one embodiment.

FIG. 3 schematically shows multiple test signals according to one embodiment, which have a waveform that is asymmetric in the time domain and a combination of higher harmonics.

FIG. 4 schematically shows time derivatives of the multiple test signals from FIG. 3.

FIG. 5 schematically shows a comparison signal formed by comparing a derivative of a test signal with a threshold value.

FIG. 6 schematically shows a further test device for testing wiring of an electrical installation having multiple circuits according to one embodiment.

### DETAILED DESCRIPTION OF EXEMPLARY EMBODIMENTS

The present invention is explained in more detail below on the basis of embodiments with reference to the figures. In the figures, the same reference signs denote the same or similar elements. The figures are schematic representations of various embodiments of the invention. Elements illustrated in the figures are not necessarily illustrated true to scale. Rather, the various elements illustrated in the figures are rendered in such a way that the function and purpose thereof are able to be understood by those skilled in the art.

Connections and couplings illustrated in the figures between functional units and elements may be implemented as direct or indirect connections or couplings. A connection or coupling may be implemented in wired or wireless form.

FIG. 1 schematically shows a section of an electrical installation 100 to which a test device 150 for testing wiring of the electrical installation 100 is connected. The electrical installation 100 is a multi-phase electrical installation. Many power engineering systems use a three-phase current system. In the example shown in FIG. 1, the electrical installation 100 is a three-phase system. By way of example, the electrical installation 100 may comprise a high-voltage installation or part thereof. The electrical installation 100 comprises an electrical component 110, on which two three-phase connections are provided. The electrical component 110 may include for example a three-phase circuit breaker, a three-phase transformer, multiple transformers, capacitances, current and voltage converters or intermediate converters. On a first side 112, the electrical component 110 has connections that are connected to outer conductors 120 to 122 of a three-phase power line 125. On a second side 114, the electrical component 110 has connections that are connected to outer conductors 130 to 132 of a second three-phase power line 135. The electrical component 110 may have further connections, for example for grounding or for a neutral conductor of a star-connected three-phase system, with these further connections however not being shown for reasons of clarity. Wiring errors may occur when installing the electrical component 110. By way of example, two outer conductors, for example the outer conductors 120 and 121, may be connected the wrong way round on the first side 112 of the electrical component 110. Following installation or repair of the electrical installation 100, it may therefore be necessary to check the wiring.

In order to check the wiring, the test device 150 shown in FIG. 1 may be electrically coupled to both sides 112, 114 of the electrical component 110.

The test device 150 comprises a test signal generation device 152, which generates multiple test signals. To test the three-phase electrical installation 100, the test signal generation device 152 generates for example three test signals 160 to 162. The test device 150 furthermore comprises an injection device 154 by way of which the test signals 160 to 162 are injected into multiple first connections 142 to 144 at a first point 141 of the electrical installation 100 via corresponding lines 170 to 172. The injection device 154 may for example adapt the test signals from the test signal generation device 152 to a nominal range of the electrical component 110 and provide them at three connections. A set of lines comprising the three lines 170 to 172 may be connected to the three connections of the injection device 154. At the first point 141, for example a comparatively easily accessible distribution upstream of the electrical component 110, the line 170 may be connected to the outer conductor 120, such that a first test signal is injected into the outer conductor 120. The line 171 may be connected to the outer conductor 121 in order to inject a second test signal into the outer conductor 121. The line 172 may be connected to the outer conductor 122 in order to inject a third test signal into the outer conductor 122. A corresponding test signal is thus injected into each phase on the first side 112 of the component 110.

The test device 150 furthermore comprises an acquisition device 156, which is connected, via corresponding lines 180 to 182, to the three outer conductors 130 to 132, which are connected to the second side 114 of the component 110, at a second point 145 of the electrical installation 100 via corresponding second connections 146 to 148. The second point 145 may be located on an easily accessible distribution of the electrical installation 100. A corresponding measurement signal is thus able to be acquired for each phase on the second side 114.

The test device 150 furthermore comprises a processing device 158. The processing device 158 comprises for example an electronic controller, for example a microprocessor controller, which is able for example to execute a computer program. The processing device 158 may be coupled to the test signal generation device 152 and the acquisition device 156 in order to drive them in a coordinated manner, as will be described in detail below. In other examples, the processing device 158 is not connected to the test signal generation device 152 and the test signal generation device 152 generates the test signals independently of any control by the processing device 158. It is therefore clear that the test signal generation device 152, the injection device 154, the acquisition device 156 and the processing device 158 do not necessarily have to be formed in one and the same housing or in one unit, but rather may comprise spatially independent units having their own housings. By way of example, the test signal generation device 152, together with the injection device 154, may form a unit that is able to be operated and set up independently of any other unit comprising the acquisition device 156 and the processing device 158. The test device 150 is thereby able to be used even in large electrical installations in which the first point 141 is a large distance away from the second point 145, without the need for correspondingly long lines 170 to 172 or 180 to 182.

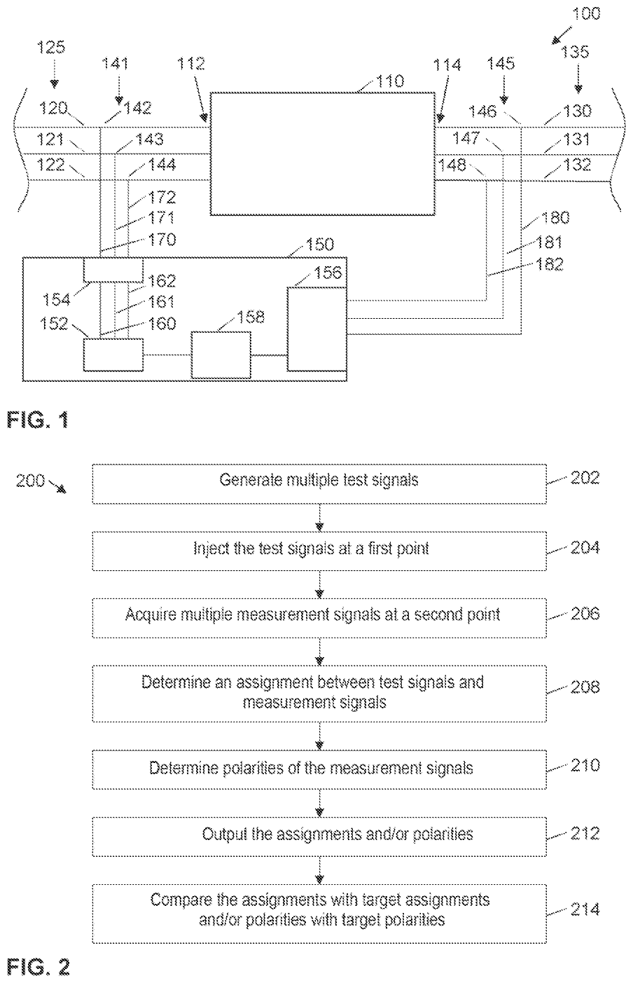

The way in which the test device 150 works will be described in detail below with reference to FIGS. 2 to 5. FIG. 2 shows a method 200 having method steps 202 to 214 that are able to be carried out by the test device 150 in order to test the wiring of the electrical installation 100. At least some of the processing steps shown in FIG. 2 may be performed in particular using the processing device 158, for example by way of a computer program that is executed by the processing device 158.

In step 202, multiple test signals are generated. In detail, a separate test signal Pₚ(t) is generated for each phase, having a waveform that is asymmetric in the time domain and a combination of harmonics from a predefined group of higher harmonics. The index p denotes the phase for which the test signal Pₚ(t) is intended. The combinations of harmonics of the multiple test signals are different, and so the test signals are also different. By way of example, the test signals may be based on a common signal P (t), which has a waveform that is asymmetric in the time domain. The waveform of the common signal P (t) may be approximated to a sawtooth waveform. For this purpose, it is possible for example to use sine signals having different amplitude and frequency, these approximating the sawtooth waveform by way of Fourier synthesis. By way of example, a signal according to the following equation may be used as common signal P (t):

$$P ( t ) = A {\sum }_{n = 1}^{k} \frac{1}{{n}^{2}} sin ( 2 π {nf}_{g} t )$$

A here represents the amplitude of the entire signal, k represents the number of harmonics used and f_{g} represents the fundamental frequency of the signal. The term 1/n² weights the individual sine functions in order overall to approximate the sawtooth waveform.

By way of example, it is possible to form a signal with A=1, k=3, and f_{g}=52.63 Hz. In other examples, A may also be selected such that a root mean square (RMS) of the signal is approximately 1. By way of example, it is possible to select A ˜ 0.962.

Each of the test signals Pₚ(t) comprises further higher harmonics. By way of example, the test signal P₁ (t) for a first phase additionally comprises the fourth harmonic, the test signal P₂ (t) for a second phase additionally comprises the fifth harmonic, whereas the test signal P₃(t) for a third phase comprises neither the fourth nor the fifth harmonic. Overall, the test signals for a three-phase system are obtained for example according to the following equation and table:

$${P}_{p} ( t ) = A {\sum }_{n = 1}^{k} {H}_{n} ( p ) sin ( 2 π {nf}_{g} t )$$

| Signal | Harmonic Hₙ (p) | | | | |
|---|---|---|---|---|---|
| n | 1 | 2 | 3 | 4 | 5 |
| P₁(t) | 1.0 | 0.25 | 0.111 . . . | 0.0625 | 0.0 |
| P₂(t) | 1.0 | 0.25 | 0.111 . . . | 0.0 | 0.04 |
| P₃(t) | 1.0 | 0.25 | 0.111 . . . | 0.0 | 0.0 |

In this case, a binary representation of the phase number p was used in principle and the amplitudes of the fourth and fifth harmonics were adapted or coded accordingly:

| Phase p | Binary representation | H₄(p) | H₅(p) |
|---|---|---|---|
| 1 | 10 | $\frac{1}{{4}^{2}} ( unchanged )$ | 0.0 (removed) |
| 2 | 01 | 0.0 (removed) | $\frac{1}{{5}^{2}} ( unchanged )$ |
| 3 | 00 | 0.0 (removed) | 0.0 (removed) |

The test signals have a waveform that is asymmetric in the time domain, as a result of which the polarity is able to be distinguished, as will be described later. The fundamental frequency of the test signals may be selected so as to give rise to a time-variable signal that is able to be transmitted via current or voltage converters of the installation 100, for example via transformers and/or capacitances. Furthermore, the test signals have substantially no DC component, as a result of which it is possible to avoid saturation of current or voltage converters. The fundamental frequency of the test signals may be selected such that they are in a favorable transmission range of the current or voltage converters. By way of example, the fundamental frequency may be close to the nominal frequency of the converters, that is to say close to the mains frequency. On the other hand, the fundamental frequency of the test signal should, as far as possible, not match the fundamental frequency or harmonics of the mains frequency that is used or other frequencies occurring in the power engineering system, in order to enable the best possible separation between test signals and interference. By way of example, the abovementioned fundamental frequency of 52.63 Hz meets these requirements for installations with a nominal frequency of 50 Hz or 60 Hz, as is apparent from the table below.

| | Fundamental | | | | |
|---|---|---|---|---|---|
| | frequency | 2nd Harm. | 3rd Harm. | 4th Harm. | 5th Harm. |
| Test signal | 52.63 Hz | 105.26 | 157.89 Hz | 210.52 Hz | 263.15 Hz |
| 50 Hz | 50.00 Hz | 100.00 Hz | 150.00 Hz | 200.00 Hz | 250.00 Hz |
| mains | | | | | |
| 60 Hz | 60.00 Hz | 120.00 Hz | 180.00 Hz | 240.00 Hz | 300.00 Hz |
| mains | | | | | |

Other frequencies greater than 50 Hz and less than 60 Hz may however also be used.

Due to the comparatively small amplitudes of the fourth and/or fifth harmonics, the asymmetric waveform changes only to an insignificant extent. Lower harmonics, such as for example the second and third harmonics, are less suitable for phase coding, since they affect the asymmetry of the signal in the time domain significantly and could therefore complicate detection, in particular of polarity. Harmonics that are even higher, in particular seventh or higher harmonics, are also less suitable, since current and voltage converters usually attenuate high frequencies to a much greater extent, and could thus impair transmission and detection.

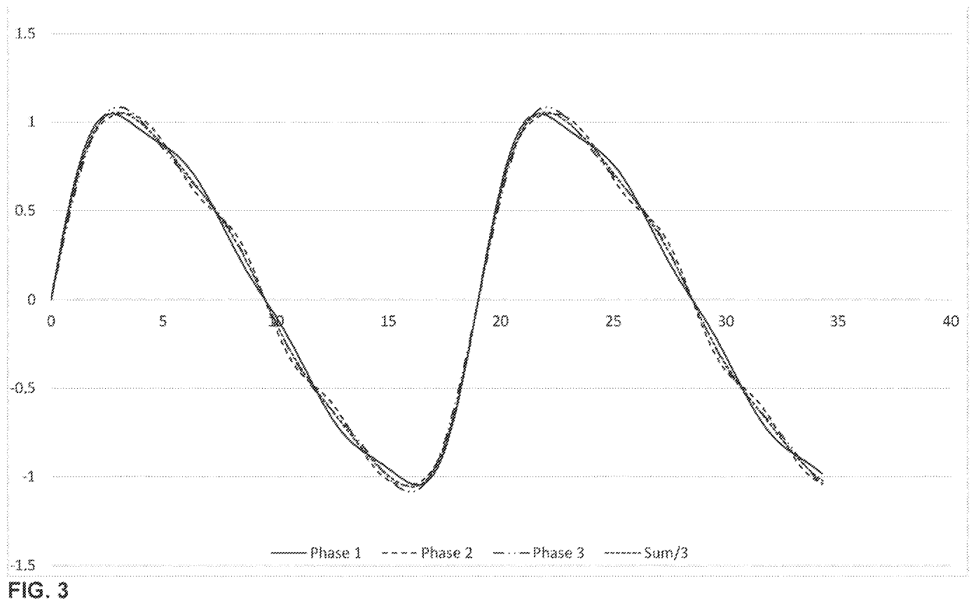

FIG. 3 shows waveforms of the test signals for the phases 1, 2 and 3 and a sum signal, divided by three, of the test signals for the phases 1, 2 and 3. As may be seen from FIG. 3, the asymmetric waveform in the time domain is clearly recognizable for all test signals and also for the sum signal, that is to say the signals all essentially have a comparatively steep rising edge and a falling edge that is comparatively shallow compared to the rising edge.

In step 204, the generated test signals 160 to 162 are injected into the outer conductors 120 to 122 at the first point 141 via the first connections 142 to 144. The test signals 160 to 162 may be injected simultaneously. The test signals injected in this way pass through the electrical component 110, which comprises for example one or more transformers or capacitances or other power engineering equipment, such as circuit breakers for example. On the second side 114, the electrical component 110 outputs output signals on the three outer conductors 130 to 132 due to the injected test signals. When an electrical component 110 is connected correctly, it is expected for example that the test signal injected on the outer conductor 120 will essentially be output on the outer conductor 130, for example with a changed voltage in the case of a transformer. However, it would be expected that the waveform would be essentially unchanged. Similarly, when the electrical component 110 is connected correctly, it is expected for example that the signal injected into the outer conductor 121 will essentially be output onto the outer conductor 131 and that the signal injected into the outer conductor 122 will essentially be output on the outer conductor 132.

In the case of incorrect wiring, in which the outer conductors 121 and 122 have been connected the wrong way round, the signal injected onto the outer conductor 121 is output, conversely, onto the outer conductor 132, and the signal injected onto the outer conductor 122 is output onto the outer conductor 131.

In step 206, multiple measurement signals are acquired at the second point 145. The multiple measurement signals may be acquired simultaneously or sequentially. In the acquisition device 156, the acquired measurement signals may optionally be pretreated, for example by filtering. By way of example, the measurement signals may be preprocessed using analog and/or digital filters in order for example to suppress interference caused by resistive, inductive or capacitive coupling, for example, a resistive voltage drop due to a current flow through a common return conductor. Such interference may affect the outer conductors 120 to 122 and 130 to 132, for example from neighboring systems that are in operation. Furthermore, for example, notch filters for mains frequencies, for example at 50 Hz, 60 Hz or 16.7 Hz or a combination thereof, may be used to filter out interference from neighboring systems. Further notch filters may be used to filter the measurement signals for higher harmonics of the mains frequency. As an alternative or in addition, low-pass filters may be applied to the measurement signals to remove higher harmonics and other interference. A cutoff frequency may in this case be higher than the frequency of the highest harmonics used in the test signals. Finally, a high-pass filter may be applied to the measurement signals to remove low-frequency interference, wherein the cutoff frequency may be lower than the fundamental frequency of the test signals. The preprocessing of the measurement signals makes it possible to increase the reliability of the wiring check and susceptibility to interference from neighboring systems that are in operation.

In step 208, an assignment between test signals and measurement signals is determined. In other words, in step 208, the test signals are identified in the measurement signals. The individual test signals may be identified in the measurement signals by way of narrow-band filters or a discrete Fourier transform for the fourth and fifth harmonics. If the fundamental frequency f_{g} has been selected appropriately as described above, for example at 52.63 Hz, there are no overlaps with the mains frequency or higher harmonics of the mains frequency.

By comparing the amplitude of the fundamental of the respective measurement signal with the amplitudes of the higher harmonics, for example with the amplitudes of the fourth and fifth harmonics, it is possible to distinguish between the waveforms P₁ (t), P₂ (t) and P₃ (t). Since the relevant harmonics of the test signal do not occur in the power engineering installation 100 during normal operation, comparisons are able to be carried out using comparatively low threshold values, for example 1% or 4% of the fundamental. Even weak signals are thereby also able to be assigned unambiguously. The following table shows one example of the detection of the test signals using the threshold value 1%.

| H4 | H5 | Detected signal |
|---|---|---|
| >1% H₁ (present) | <1% H₁ (not present) | Phase 1 P₁ (t) |
| <1% H₁ (not present) | >1% H₁ (present) | Phase 2 P₂ (t) |
| <1% H₁ (not present) | <1% H₁ (not present) | Phase 3 P₃ (t) |
| >1% H₁ (present) | >1% H₁ (present) | Sum signal P_{S} (t) |

By way of example, the test signal P₁ (t) is detected when the amplitude of the fourth harmonic is greater than 1% of the amplitude of the fundamental and the amplitude of the fifth harmonic is less than 1% of the amplitude of the fundamental. The test signal P₂ (t) is detected when the amplitude of the fourth harmonic is less than 1% of the amplitude of the fundamental and the amplitude of the fifth harmonic is greater than 1% of the amplitude of the fundamental. The test signal P₃ (t) is detected when the amplitude of the fourth harmonic is less than 1% of the amplitude of the fundamental and the amplitude of the fifth harmonic is less than 1% of the amplitude of the fundamental. A sum signal of the three test signals P₁ (t), P₂ (t) and P₃ (t) contains both the fourth and the fifth harmonic, such that the sum signal Pₛ(t) is detected when the amplitude of the fourth harmonic is greater than 1% of the amplitude of the fundamental and the amplitude of the fifth harmonic is greater than 1% of the amplitude of the fundamental.

In the above example, the test signals were generated using in each case a different combination of fourth and fifth harmonics. In order for example to achieve greater robustness, further harmonics may be used. By way of example, the following table shows coding using the fourth, fifth, and sixth harmonics with a Hamming distance of two and an even parity.

| Phase p | Coding | H₄(p) | H₅(p) | H₆(p) |
|---|---|---|---|---|
| 1 | 100 | $\frac{1}{{4}^{2}} ( present )$ | 0 (not present) | 0 (not present) |
| 2 | 010 | 0 (not present) | $\frac{1}{{5}^{2}} ( present )$ | 0 (not present) |
| 3 | 001 | 0 (not present) | 0 (not present) | $\frac{1}{{6}^{2}} ( present )$ |

In further examples, it is possible to use not only the presence or absence of a harmonic for coding, but also amplitude. By way of example, it is possible to use only the fourth harmonic, but having different amplitudes for the different test signals:

| Phase p | Coding | H₄(p) |
|---|---|---|
| 1 | 00 | $\frac{1}{{4}^{2}}$ |
| 2 | 01 | $\frac{2}{3} \frac{1}{{4}^{2}}$ |
| 3 | 10 | $\frac{1}{3} \frac{1}{{4}^{2}}$ |

The threshold values for detecting the different amplitudes of the fourth harmonic need to be adapted accordingly. In the example shown above, comparatively small amplitudes were used for the fourth harmonic. The amplitude of a harmonic, for example the fourth harmonic, may also be selected to be larger, that is to say larger than 1/16, for example. It should be noted here that the asymmetry in the time domain remains to a sufficiently significant extent. With appropriate coding, it is thus possible to distinguish between not only individual phases, but also different phase combinations.

Based on the assignment between test signals and measurement signals determined in step 208, it is easily possible to establish whether the expected test signals have been acquired at the corresponding outer conductors 130 to 132. In the case of assignments that are not as expected, incorrect wiring may be established.

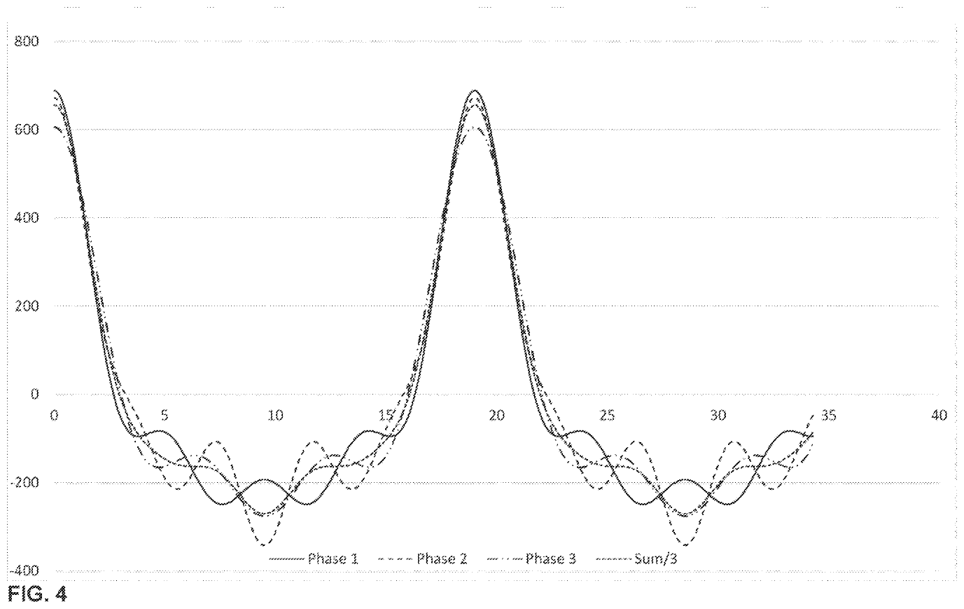

In step 210, polarities of the measurement signals that were acquired at the second point 145 are determined. The polarity is detected based on the waveform that is asymmetric in the time domain. For the measurement signals, which may be pretreated as described above, respective derivatives are formed in the time domain. A respective derivative may be ascertained for example through a time-discrete numerical differentiation using differences between signal levels acquired in temporal succession or implicitly through appropriately adapted filter structures, for example by using an analog operational amplifier as a differentiation circuit or in digital filter structures. FIG. 4 shows resulting derivatives dMₚ(t)/dt for the measurement signals Mₚ(t) for the phases p=1, 2 and 3 and for the sum signal. A corresponding auxiliary signal Qₚ(t) may be formed for each of the derivatives, for example according to the following rule:

$${Q}_{p} ( t ) = \{ \begin{matrix}1 , if \frac{{M}_{p} ( t )}{dt} > δ \\ - 1 , if \frac{{M}_{p} ( t )}{dt} < - δ \\ 0 , otherwise\end{matrix}$$

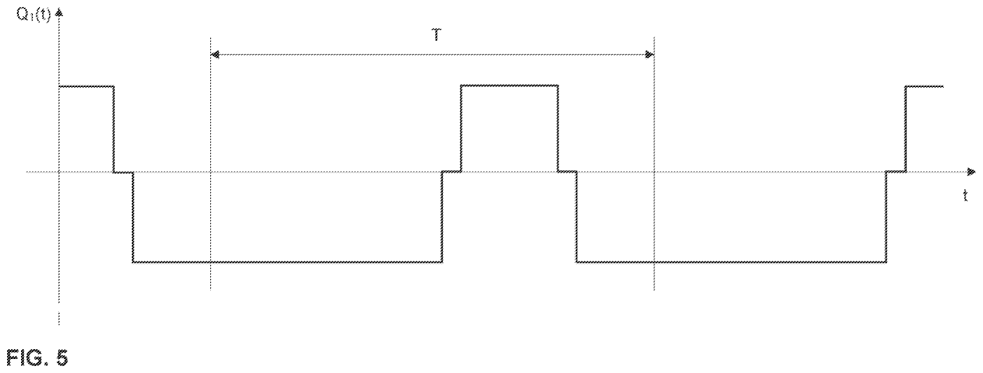

In this case, δ is a threshold value used to suppress noise and other undesired interference. FIG. 5 shows, by way of example, the auxiliary signal Q₁ (t) for the test signal for phase 1. Based on the auxiliary signal Qₚ(t), a corresponding average Qy (t) is calculated over a certain time. This average may be calculated for example over a discrete time, for example a period duration T of the fundamental of the test signals or continuously by way of a low-pass filter. If this average exceeds a defined positive threshold, then a positive polarity is indicated (short rising edge and long falling edge). If the average falls below a defined negative threshold, a negative polarity is indicated (long rising edge and short falling edge). A polarity change, which may occur for example due to incorrect wiring, is thus able to be determined easily for each phase.

In step 212, the phase assignments and polarities determined in this way may be output, for example, on a display device for a user.

By way of example, a first test signal for phase 1 may be output on line 170, a second test signal for phase 2 may be output on line 171, and a third test signal for phase 3 may be output on line 172. If the electrical installation 100 is wired correctly, the test device 150 indicates, for the line 180, that the first test signal has been detected, for the line 181, that the second test signal has been detected, and for the line 182, that the third test signal has been detected. The test device 150 may furthermore indicate that the test signals were each output and detected with a positive polarity. Wiring errors, for example mixed-up outer conductors or incorrect wiring leading to a polarity reversal, for example at a transformer, are able to be identified by an operator based on the outputs.

As an alternative or in addition, in step 214, the detected phase assignments may be compared with target assignments and/or the detected polarities may be compared with target polarities and a warning may be output automatically if a deviation between the detected state and the target state has been established.

The electrical installation 100 may also have further connections, for example further three-phase connections, the wiring of which may be checked in the same way as described above. These connections may for example concern auxiliary circuits or control circuits, which may also be tested using the above method, depending on the type of circuit.

If multiple circuits or phases are tested, they may use a common neutral conductor (N for L1, L2 and L3) or be completely separate circuits (L1+N1, L2+N2, L3+N3). In this case too, various wiring errors are conceivable and are able to be detected using the method. Multiple ground connections may occur in the event of wiring errors. By way of example, a current clamp may be used to measure the current via the ground connection as one of the multiple measurement signals. The described method makes it possible, using the assignments, to detect which test signals were able to be detected in the ground connection, and thus makes it possible to identify desired and undesired ground connections.

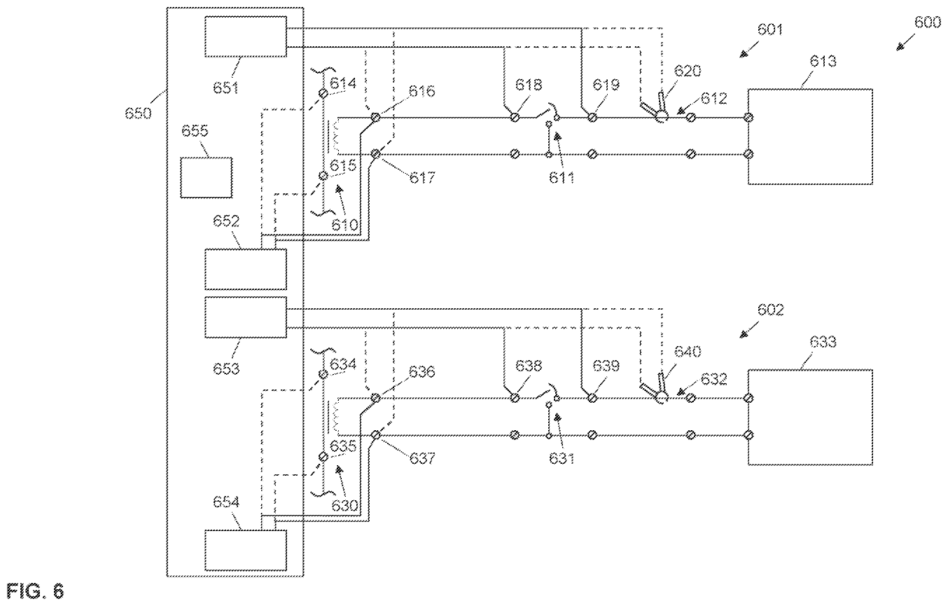

FIG. 6 schematically shows a section of a further electrical installation 600 to which a test device 650 for testing wiring of the electrical installation 600 is connected. The electrical installation 600 comprises multiple circuits that may be assigned to one or more phases. In the example shown in FIG. 6, the electrical installation 600 comprises two circuits 601 and 602 that are essentially separate from one another. However, the circuits 601 and 602 may also be assigned to one phase of a multi-phase system, that is to say the same phase of the multi-phase system, or to multiple different phases of a multi-phase system, or may be connected to one another via their neutral conductors. In other examples, the electrical installation 600 may comprise more than two circuits. By way of example, the electrical installation 600 may comprise a high-voltage installation or part thereof. Each of the circuits 601 and 602 may comprise one or more electrical components, for example current or voltage converters 610, 630, secondary wiring 612, 632, matching converters, test plugs 614-619, 634-639, test switches 611, 631, counters and/or protective devices, such as for example relays 613, 633.

Following installation or repair of the electrical installation 600, it may be necessary to check the wiring. In order to check the wiring, the test device 650 shown in FIG. 6 may be electrically coupled to both circuits 601 and 602.

The test device 650 comprises multiple test signal generation devices that generate multiple test signals. FIG. 6 shows two test signal generation devices 652 and 654 for generating two test signals. The multiple test signals may also be generated by a common test signal generation device. Each of the test signal generation devices 652 and 654 is assigned a corresponding injection device (not shown) by way of which the test signals are injected into the electrical installation 600 at corresponding injection points via corresponding lines. The injection devices may for example adapt the test signals from the test signal generation devices 652, 654 to a nominal range required at the corresponding injection point. In the example shown in FIG. 6, the test signal from the test signal generation device 652 may be injected for example at test plugs 616, 617 on a secondary side of a converter 610, for example a current converter or voltage converter. As an alternative, the test signal from the test signal generation device 652 may also be injected at test plugs 614, 615 on a primary side of the converter 610, as shown by the dashed lines. Injection on the primary side makes it possible to additionally check the polarity and wiring of the converter 610. In the case of injection on the primary side, correspondingly higher currents may be required for current converters and correspondingly higher voltages may be required for voltage converters. Likewise, the test signal from the test signal generation device 654 may be injected for example at test plugs 636, 637 on a secondary side of a converter 630. As an alternative, the test signal from the test signal generation device 654 may also be injected at test plugs 634, 635 on a primary side of the converter 630, as shown by the dashed lines, in order to additionally check the polarity and wiring of the converter 630.

The test device 650 furthermore comprises multiple acquisition devices for acquiring measurement signals. In the example of FIG. 6, the test device 650 comprises two acquisition devices 651 and 653, which are coupled to the first and second circuit 601, 602, respectively, via corresponding lines. By way of example, the acquisition device 651 may be coupled to test plugs 618, 619 at the test switch 611 in order to acquire a voltage at the test switch 611 as a measurement signal. As illustrated by the dashed lines, the acquisition device 651 may, as an alternative, be coupled to test plugs 616, 617 in order to acquire a voltage on the secondary side of the converter 610 or to a current clamp 620 in order to acquire a current through the wiring 612. In the same way, the acquisition device 653 may be coupled to the second circuit 602. As shown in FIG. 6, the acquisition device 653 may be coupled to the test plugs 638, 639 at the test switch 631 in order to acquire a voltage at the test switch 631 as a measurement signal. As an alternative, the acquisition device 653 may be coupled to test plugs 636, 637 in order to acquire a voltage on the secondary side of the converter 630 or to a current clamp 640 in order to acquire a current through the wiring 632.

The test device 650 furthermore comprises a processing device 655, which is shown as a separate component in FIG. 6. In other examples, the processing device 655 may also be designed so as to be integrated with one of the test signal generation devices 652, 654 or the detection devices 651, 653. The processing device 655 comprises for example an electronic controller, for example a microprocessor controller, which is able for example to execute a computer program. The processing device 655 may be coupled to the test signal generation devices 652, 654 and the acquisition devices 651, 653 in order to drive them in a coordinated manner, as will be described in detail below. In other examples, the processing device is not connected to the test signal generation devices 652, 654, and the test signal generation devices 652, 654 generate the test signals independently of any control by the processing device 655. The test signal generation devices 652, 654, the acquisition devices 651, 653 and the processing device 655 do not have to be formed in one and the same housing or in one unit, but rather may comprise spatially independent units having their own housings. By way of example, the test signal generation devices 652, 654 may each form a unit that is able to be operated and set up independently. A further unit may comprise the acquisition devices 651, 653 and the processing device 655 and be coupled to the test signal generation devices 652, 654. The test device 650 is thereby able to be used even in large electrical installations in which the injection points are a large distance away from the measuring points, without the need for correspondingly long lines between the test signal generation devices 652, 654 and the corresponding injection points.

The way in which the test device 650 works corresponds essentially to the way in which the test device 150 works, as described in detail above with reference to FIGS. 1 to 5. As described above, the method 200 shown in FIG. 2 may be carried out by the test device 650 in order to test the wiring of the electrical installation 600.

In step 202, two test signals are generated in this case. A separate test signal Pₚ(t) is generated for each circuit 601, 602, having a waveform that is asymmetric in the time domain and a combination of harmonics from a predefined group of higher harmonics. The index p denotes the circuit for which the test signal Pₚ(t) is intended, for example p=1 for the circuit 601 and p=2 for the circuit 602. The combinations of harmonics of the multiple test signals are different, and so the test signals are also different. By way of example, the test signals may be based on a common signal P (t), which has a waveform that is asymmetric in the time domain. The waveform of the common signal P (t) may be approximated to a sawtooth waveform. For this purpose, it is possible for example to use sine signals having different amplitude and frequency, these approximating the sawtooth waveform by way of Fourier synthesis. By way of example, a signal according to the following equation may be used as common signal P (t):

$$P ( t ) = A {\sum }_{n = 1}^{k} \frac{1}{{n}^{2}} sin ( 2 π {nf}_{g} t )$$

A here represents the amplitude of the entire signal, k represents the number of harmonics used and f_{g} represents the fundamental frequency of the signal. The term

$$\frac{1}{{n}^{2}}$$

weights the individual sine functions in order overall to approximate the sawtooth waveform.

By way of example, it is possible to form a signal with A=1, k=3, and f_{g}=52.63 Hz. In other examples, A may also be selected such that a root mean square (RMS) of the signal is approximately 1.

Each of the test signals Pₚ(t) comprises further higher harmonics. By way of example, the test signal P₁ (t) additionally comprises the fourth harmonic and the test signal P₂ (t) additionally comprises the fifth harmonic. Overall, the test signals for the two circuits 601, 602 are obtained for example according to the following equation and table:

$${P}_{p} ( t ) = A {\sum }_{n = 1}^{k} {H}_{n} ( p ) sin ( 2 π {nf}_{g} t )$$

| Signal | Harmonic Hₙ (p) | | | | |
|---|---|---|---|---|---|
| n | 1 | 2 | 3 | 4 | 5 |
| P₁(t) | 1.0 | 0.25 | 0.111 . . . | 0.0625 | 0.0 |
| P₂(t) | 1.0 | 0.25 | 0.111 . . . | 0.0 | 0.04 |

In this case, a binary representation of the circuit number p was used in principle and the amplitudes of the fourth and fifth harmonics were adapted or coded accordingly:

| Circuit p | Binary representation | H₄(p) | H₅(p) |
|---|---|---|---|
| 1 | 10 | $\frac{1}{{4}^{2}} ( unchanged )$ | 0.0 (removed) |
| 2 | 01 | 0.0 (removed) | $\frac{1}{{5}^{2}} ( unchanged )$ |

If further circuits are to be incorporated into the check, then corresponding binary representations may be used to adapt the higher harmonics accordingly. In the case of more than four circuits, further harmonics may be used, for example H₆ (p) and/or H₇(p). The test signals have a waveform that is asymmetric in the time domain, as a result of which the polarity is able to be distinguished, as will be described later. The fundamental frequency of the test signals may be selected so as to give rise to a time-variable signal that is able to be transmitted via current or voltage converters of the installation 600, for example via transformers and/or capacitances. Details in this regard were discussed above in conjunction with FIGS. 1 to 5 and apply to the example of FIG. 6 in the same manner, wherein for example the phase 1 corresponds to the circuit 601 and the phase 2 corresponds to the circuit 602.

In step 204, the generated test signals are injected into the circuits 601, 602, as described above. The test signals may be injected simultaneously. The test signals injected in this way pass through the electrical components, which comprise for example one or more transformers or capacitances or other power engineering equipment, such as circuit breakers or test switches for example. Output signals are generated at the measuring points described above on the basis of the injected test signals. When electrical components are connected correctly, it is expected for example that the test signal injected into the circuit 601 will essentially be output at the test plugs 618, 619 of the test switch 611, for example with a changed voltage in the case of injection at the test plugs 614, 615. However, it would be expected that the waveform would be essentially unchanged. Likewise, when electrical components are connected correctly, it is expected for example that the signal injected into the circuit 602 will essentially be output at the test plugs 638, 639 of the test switch 631.

In the case of incorrect wiring, in which for example lines of the first circuit 601 and lines of the second circuit 602 have been connected the wrong way round, the signal injected into the first circuit 601 could, conversely, be present in the second circuit 602 and/or the signal injected into the second circuit 602 could be present in the first circuit 601.

In step 206, multiple measurement signals are acquired, for example as described above, at the test switches 611 and 631. The multiple measurement signals may be acquired simultaneously or sequentially. In the acquisition devices 651, 653, the acquired measurement signals may optionally be pretreated, for example by filtering.

In step 208, an assignment between test signals and measurement signals is determined. In other words, in step 208, the test signals are identified in the measurement signals. The individual test signals may be identified in the measurement signals by way of narrow-band filters or a discrete Fourier transform for the fourth and fifth harmonics.

By comparing the amplitude of the fundamental of the respective measurement signal with the amplitudes of the higher harmonics, for example with the amplitudes of the fourth and fifth harmonics, it is possible to distinguish between the waveforms P₁ (t) and P₂ (t). Since the relevant harmonics of the test signal do not occur in the power engineering installation 600 during normal operation, comparisons are able to be carried out using comparatively low threshold values, for example 1% or 4% of the fundamental. Even weak signals are thereby also able to be assigned unambiguously.

Based on the assignment between test signals and measurement signals determined in step 208, it is easily possible to establish whether the expected test signals have been acquired at the corresponding test plugs 618, 619, 638 and 639. In the case of assignments that are not as expected, incorrect wiring may be established.

In step 210, polarities of the measurement signals that were acquired at the test plugs 618, 619, 638 and 639 are determined. The polarity is detected based on the waveform that is asymmetric in the time domain, as described above with reference to the electrical installation 150.

In step 212, the circuit assignments and polarities determined in this way may be output, for example, on a display device for a user.

As an alternative or in addition, in step 214, the detected circuit assignments may be compared with target assignments and/or the detected polarities may be compared with target polarities. A warning may be output automatically if a deviation between the detected state and the target state has been established.

In summary, the different test signals described above, which have a waveform that is asymmetric in the time domain and different combinations of higher harmonics, enable a fast and reliable check of the wiring of the electrical installation. Since the test signals are free from DC current, no saturation effects occur in transformers or capacitances, for example, such that the test signals are able to be transmitted via converters without any problems. Moreover, the test signals allow detection of polarity errors and unambiguous distinction of the individual phases. The threshold values, which are used here to identify the higher harmonics, may be selected so as to be relative with respect to the fundamental, and are thus not dependent on the absolute amplitude of the signals. The method therefore also works with partial signals, which may occur for example due to current division or in the case of undesirable ground connections. Larger threshold values may also be used, for example 4% instead of 1%. The method thereby also tolerates frequency-dependent amplitude changes, for example a frequency response in the case of converters.

It is not necessary to evaluate the phase position for the individual test signals and the harmonics of the test signals. This method therefore tolerates relatively small phase shifts, such as for example a frequency-dependent phase response in the case of converters. Moreover, no synchronization between the test signal generation device and the acquisition device is necessary.

The individual different test signals, and also linear combinations thereof, have the same asymmetric properties in the time domain and are therefore able to be assigned reliably to a polarity.

Using additional harmonics and/or additional different amplitudes makes it possible to distinguish between more than three phases. This makes it possible for example to distinguish simultaneously between further phases, for example in 2×3 phase systems, or to use coding with a Hamming distance greater than one in order to improve robustness to amplitude errors.

1. A method for testing wiring of an electrical installation having multiple circuits, comprising:
generating multiple test signals, wherein each of the multiple test signals has a waveform that is asymmetric in the time domain and a combination of harmonics from a predefined group of higher harmonics, wherein the combinations of harmonics of the multiple test signals are different,
injecting the multiple test signals into multiple first connections, which are assigned to the multiple circuits, at a first point of the electrical installation, wherein a different test signal of the multiple test signals is injected into each first connection of the multiple first connections,
acquiring multiple measurement signals at multiple second connections, which are assigned to the multiple circuits, at a second point of the electrical installation, and
determining assignments between in each case a first connection of the multiple first connections and a second connection of the multiple second connections on the basis of the injected test signals and the acquired measurement signals.

2. The method as claimed in claim 1, wherein the multiple test signals are injected simultaneously into the multiple first connections.

3. The method as claimed in claim 1, wherein the predefined group of higher harmonics comprises fourth and fifth harmonics.

4. The method as claimed in claim 1, wherein the waveform that is asymmetric in the time domain comprises, in addition to a fundamental, at least one of a second harmonic and a third harmonic.

5. The method as claimed in claim 1, wherein a fundamental of the waveform that is asymmetric in the time domain has a frequency different from a mains frequency of the electrical installation.

6. The method as claimed in claim 1, wherein a fundamental of the waveform that is asymmetric in the time domain has one of a frequency in the range of 50 to 60 Hz, a frequency in the range of 51 to 55 Hz, and a frequency of 52.63 Hz.

7. The method as claimed in claim 1, wherein an amplitude of an nth harmonic of the group of higher harmonics has an amplitude factor of 1/n² relative to an amplitude of a fundamental of the waveform that is asymmetric in the time domain.

8. The method as claimed in claim 1, wherein determining assignments comprises:
filtering the measurement signals using bandpass filters the center frequencies of which correspond to the frequencies of the harmonics from the predefined group of higher harmonics, and
comparing the filtered measurement signals with a threshold value.

9. The method as claimed in claim 1, wherein determining assignments comprises:
determining amplitudes of frequencies in the measurement signals that correspond to the frequencies of the harmonics from the predefined group of higher harmonics, and
comparing the determined amplitudes with a threshold value.

10. The method as claimed in claim 8, wherein the threshold value is set on the basis of an amplitude of a fundamental of the waveform that is asymmetric in the time domain.

11. The method as claimed in claim 1, wherein a first combination of the different combinations has a fourth harmonic and no fifth harmonic, a second combination of the different combinations has a fifth harmonic and no fourth harmonic, and a third combination of the different combinations has neither the fourth nor the fifth harmonic.

12. The method as claimed in claim 1, wherein a first combination of the different combinations has a fourth harmonic and no fifth and no sixth harmonic, a second combination of the different combinations has a fifth harmonic and no fourth and no sixth harmonic, and a third combination of the different combinations has a sixth harmonic and no fourth and no fifth harmonic.

13. The method as claimed in claim 1,
wherein a first combination of the different combinations has only a certain higher harmonic having a first amplitude factor, a second combination of the different combinations has only the certain higher harmonic having a second amplitude factor, and a third combination of the different combinations has only the certain higher harmonic having a third amplitude factor,
wherein the first, second and third amplitude factors are different.

14. The method as claimed in claim 1, furthermore comprising one or both of:
outputting the assignments between in each case a first connection of the multiple first connections and a second connection of the multiple second connections to a user, and/or
comparing the assignments between in each case a first connection of the multiple first connections and a second connection of the multiple second connections with predefined assignments between in each case a first connection of the multiple first connections and a second connection of the multiple second connections.

15. The method as claimed in claim 1, furthermore comprising:
determining polarities of the acquired measurement signals in order to test the wiring of the electrical installation depending on the determined polarities.

16. The method as claimed in claim 15, wherein determining polarities of the acquired measurement signals for a respective measurement signal of the acquired measurement signals comprises:
determining a derivative of a respective measurement signal,
generating a comparison signal by comparing the derivative with a threshold value,
determining an average of the comparison signal, and
determining the polarity of the respective measurement signal on the basis of the average of the comparison signal.

17. The method as claimed in claim 15, wherein
determining polarities of the acquired measurement signals for a respective measurement signal of the acquired measurement signals comprises:
determining a correlation factor on the basis of a respective measurement signal and the waveform that is asymmetric in the time domain, and
determining the polarity of the respective measurement signal on the basis of the correlation factor.

18. A test device for testing wiring of an electrical installation having multiple circuits, comprising:
a test signal generation device that is configured to generate multiple test signals, wherein each of the multiple test signals has a waveform that is asymmetric in the time domain and a combination of harmonics from a predefined group of higher harmonics, wherein the combinations of harmonics of the multiple test signals are different,
an injection device that is configured to inject the multiple test signals into multiple first connections, which are assigned to the multiple circuits, at a first point of the electrical installation, wherein a different test signal of the multiple test signals is injected into each first connection of the multiple first connections,
an acquisition device that is configured to acquire multiple measurement signals at multiple second connections, which are assigned to the multiple circuits, at a second point of the electrical installation, and
a processing device that is configured to determine assignments between in each case a first connection of the multiple first connections and a second connection of the multiple second connections on the basis of the injected test signals and the acquired measurement signals.

19. The test device as claimed in claim 18, wherein an amplitude of an nth harmonic of the group of higher harmonics has an amplitude factor of 1/n² relative to an amplitude of a fundamental of the waveform that is asymmetric in the time domain.

20. The test device as claimed in claim 18, wherein the processing device, for determining assignments, is configured to:
determine amplitudes of frequencies in the measurement signals that correspond to the frequencies of the harmonics from the predefined group of higher harmonics, and
compare the determined amplitudes with a threshold value.
